(19) United States
(12) Patent Application Publication
(10) Pub. No.: US 2024/0179975 A1
(43) Pub. Date: May 30, 2024

(54) DISPLAY PANEL AND DISPLAY DEVICE

(71) Applicant: Wuhan Tianma Microelectronics Co., Ltd., Wuhan (CN)

(72) Inventor: Chao YU, Wuhan (CN)

(73) Assignee: Wuhan Tianma Microelectronics Co., Ltd., Wuhan (CN)

(21) Appl. No.: 18/433,569

(22) Filed: Feb. 6, 2024

(30) Foreign Application Priority Data
Jul. 14, 2023 (CN) 202310870898.7

(51) Int. Cl. H10K 59/131; H10K 59/122

(52) U.S. Cl. CPC H10K 59/131; H10K 59/122

(57) ABSTRACT

Provided are a display panel and a display device. The display panel includes a display region and a non-display region at least partially surrounding the display region. The display region includes auxiliary power lines. The non-display region includes a first power main body and a first power bus. The auxiliary power lines are electrically connected to the first power main body through the first power bus. Accordingly, the auxiliary power lines are disposed in the display region and electrically connected to the first power main body through the first power bus disposed in the non-display region. The first power main body is used to supply a power voltage to the auxiliary power lines in the display region through the first power bus.

### CROSS-REFERENCE TO RELATED APPLICATION(S)

This application claims priority to Chinese Patent Application No. 202310870898.7 filed Jul. 14, 2023, the disclosure of which is incorporated herein by reference in its entirety.

### TECHNICAL FIELD

The present disclosure relates to the field of display technology and, in particular, to a display panel and a display device.

### BACKGROUND

The display principle of an organic light-emitting diode (OLED) display panel is different from a conventional liquid crystal display panel (LCD). Because no backlight source is needed in the OLED display panel, an OLED in the OLED display panel may be formed using a very thin organic material coating. Based on the feature of self-luminescence, when a current passes through the organic material coating, the organic material emits light based on the energy released by carrier recombination. Compared with the conventional LCD, the OLED display panel may be made of a thinner and lighter material so that the OLED display panel can be made thinner and lighter with a larger visual angle and can save power significantly.

With the development of OLED display panels, panel architecture emerges one after another. The present disclosure provides a display panel, aiming at providing a new idea for the design of display panels.

### SUMMARY

To solve the preceding technical problem or at least partially solve the preceding technical problem, the present disclosure provides a display panel and a display device.

In a first aspect, an embodiment of the present disclosure provides a display panel. The display panel includes a display region and a non-display region at least partially surrounding the display region.

The display region includes auxiliary power lines.

The non-display region includes a first power main body and a first power bus.

The auxiliary power lines are electrically connected to the first power main body through the first power bus.

In a second aspect, the present disclosure further provides a display device including any preceding display panel.

### BRIEF DESCRIPTION OF DRAWINGS

The drawings described herein, which are incorporated in the specification and form part of the specification, illustrate embodiments of the present disclosure and are intended to explain the principles of the present disclosure together with the description of the drawings.

To illustrate technical solutions in embodiments of the present disclosure or in the related art more clearly, the drawings used in the description of embodiments or the related art are briefly described below. Apparently, those of ordinary skill in the art may obtain other drawings based on the drawings described below on the premise that no creative work is done.

FIG. 1 is a structural diagram of a display panel according to an embodiment of the present disclosure.

FIG. 2 is a diagram illustrating an enlarged structure of a region Q1 in the display panel shown in FIG. 1.

FIG. 3 is a diagram illustrating an enlarged structure of a region Q2 in the enlarged structure shown in FIG. 2.

FIG. 4 is a structural diagram of another display panel according to an embodiment of the present disclosure.

FIG. 5 is a structural diagram of another display panel according to an embodiment of the present disclosure.

FIG. 6 is a structural diagram of another display panel according to an embodiment of the present disclosure.

FIG. 7 is a structural diagram of another display panel according to an embodiment of the present disclosure.

FIG. 8 is a structural diagram of another display panel according to an embodiment of the present disclosure.

FIG. 9 is a structural diagram of another display panel according to an embodiment of the present disclosure.

FIG. 10 is a sectional view taken along a section line A1-A2 in FIG. 9.

FIG. 11 is a structural diagram of another display panel according to an embodiment of the present disclosure.

FIG. 12 is a structural diagram of another display panel according to an embodiment of the present disclosure.

FIG. 13 is a structural diagram of another display panel according to an embodiment of the present disclosure.

FIG. 14 is a diagram illustrating an enlarged structure of a region Q4 in the display panel shown in FIG. 5.

FIG. 15 is a diagram illustrating an enlarged structure of a region Q3 in the display panel shown in FIG. 5.

FIG. 16 is a structural diagram of another display panel according to an embodiment of the present disclosure.

FIG. 17 is a structural diagram of another display panel according to an embodiment of the present disclosure.

FIG. 18 is a diagram of the electronic element structure of a pixel driving circuit according to an embodiment of the present disclosure.

FIG. 19 is a drive timing graph of a pixel driving circuit according to an embodiment of the present disclosure.

FIG. 20 is a structural diagram of another display panel according to an embodiment of the present disclosure.

FIG. 21 is a structural diagram of another display panel according to an embodiment of the present disclosure.

FIG. 22 is a structural diagram of another display panel according to an embodiment of the present disclosure.

FIG. 23 is a structural diagram of another display panel according to an embodiment of the present disclosure.

FIG. 24 is a sectional view of a display panel according to an embodiment of the present disclosure.

FIG. 25 is a structural diagram of another display panel according to an embodiment of the present disclosure.

FIG. 26 is a sectional view of another display panel according to an embodiment of the present disclosure.

FIG. 27 is a structural diagram of another display panel according to an embodiment of the present disclosure.

FIG. 28 is a structural diagram of another display panel according to an embodiment of the present disclosure.

FIG. 29 is a structural diagram of another display panel according to an embodiment of the present disclosure.

FIG. 30 is a structural diagram of another display panel according to an embodiment of the present disclosure.

FIG. 31 is a structural diagram of another display panel according to an embodiment of the present disclosure.

FIG. 32 is a structural diagram of a display device according to an embodiment of the present disclosure.

### DETAILED DESCRIPTION

For a better understanding of the preceding object, features and advantages of the present disclosure, solutions of the present disclosure are further described below. It is to be noted that if not in collision, embodiments of the present disclosure and features therein may be combined with each other.

Many details are set forth in the following description for a full understanding of the present disclosure, and the present disclosure may be implemented in other manners not described herein. Apparently, embodiments in the specification are part, not all, of the embodiments of the present disclosure.

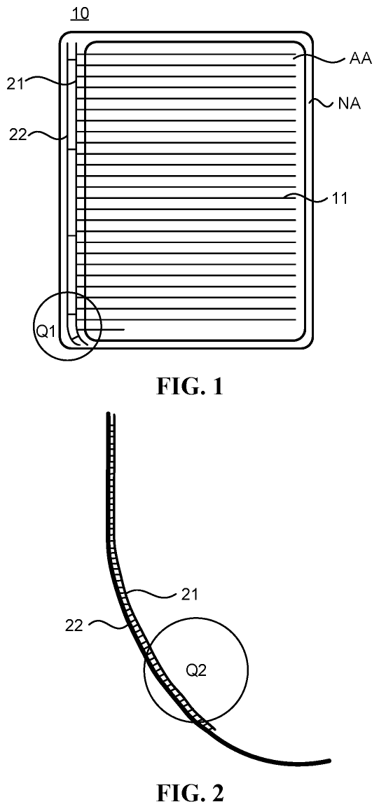

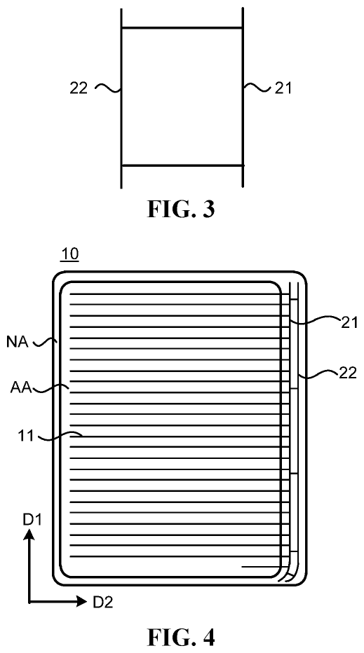

FIG. 1 is a structural diagram of a display panel according to an embodiment of the present disclosure and illustrates a planar overall structure of the display panel. FIG. 2 is a diagram illustrating an enlarged structure of a region Q1 in the display panel shown in FIG. 1 and a detailed structure of the wiring in the region Q1 is shown in FIG. 2. FIG. 3 is a diagram illustrating an enlarged structure of a region Q2 in the enlarged structure shown in FIG. 2. FIGS. 2 and 3 each illustrate the associated connection relationship between a first power bus and a first power main body. Referring to FIGS. 1 to 3, the display panel includes a display region AA and a non-display region NA at least partially surrounding the display region AA. The display region AA includes auxiliary power lines 11. The non-display region NA includes a first power main body 22 and a first power bus 21. The auxiliary power lines 11 are electrically connected to the first power main body 22 through the first power bus 21.

The display region AA is configured to display an image and may include sub-pixels arranged in an array. A sub-pixel includes a pixel driving circuit and a light-emitting element to implement active light emission control and image display. The non-display region NA at least partially surrounds the display region AA. For example, the non-display region NA may be disposed in at least part of a space on at least one side of the display region AA and the non-display region NA is used to arrange a peripheral circuit and wires so as to transmit signals for display to the display region AA, such as driving signals and power signals. The non-display region NA is not used to display the image, and the non-display region NA may also be referred to as a bezel region. The smaller the ratio of the non-display region NA to the planar area of the display panel 10, the greater the ratio of the display region AA and the easier it is to achieve a narrow bezel and a full screen.

The auxiliary power lines 11 are disposed in the display region AA and configured to compensate for the wiring non-uniformity in the display region AA, thereby improving the wiring uniformity in the display region AA. Moreover, the auxiliary power lines 11 can transmit power signals, for example, PVEE signals, thereby balancing voltage drops at different positions in the display panel 10 and improving display uniformity.

The first power main body 22 and the first power bus 21 are each located in the non-display region NA. The first power main body 22 may be disposed on one side of the first power bus 21 facing away from the display region AA. That is, the first power bus 21 is disposed on one side of the first power main body 22 facing towards the display region AA. Exemplarily, the auxiliary power lines 11 in the display region AA extend in the non-display region NA. The extension direction of the auxiliary power lines 11 may intersect the extension direction of the first power main body 22. The extension direction of the first power bus 21 may be the same as the extension direction of the first power main body 22. The extension direction of the auxiliary power lines 11 may intersect the extension direction of the first power bus 21. For example, the extension direction of the auxiliary power lines 11 may be perpendicular to the extension direction of the first power bus 21. Accordingly, the auxiliary power lines 11 are electrically connected to the first power main body 22 through the first power bus 21.

Exemplarily, referring to FIG. 1, the auxiliary power lines 11 extend in the lateral direction. The first power bus 21 and the first power main body 22 may extend in the longitudinal direction. Alternatively, in other embodiments, the auxiliary power lines may also extend in the longitudinal direction, and the first power bus 21 and the first power main body 22 may extend in the lateral direction. This is not limited here.

In this specification, the lateral direction may be the extension direction of scan lines in the display panel, and the longitudinal direction may be the extension direction of data lines in the display panel. Of course, the lateral direction and the longitudinal direction may also be understood with reference to other wires in the display panel and are not limited here.

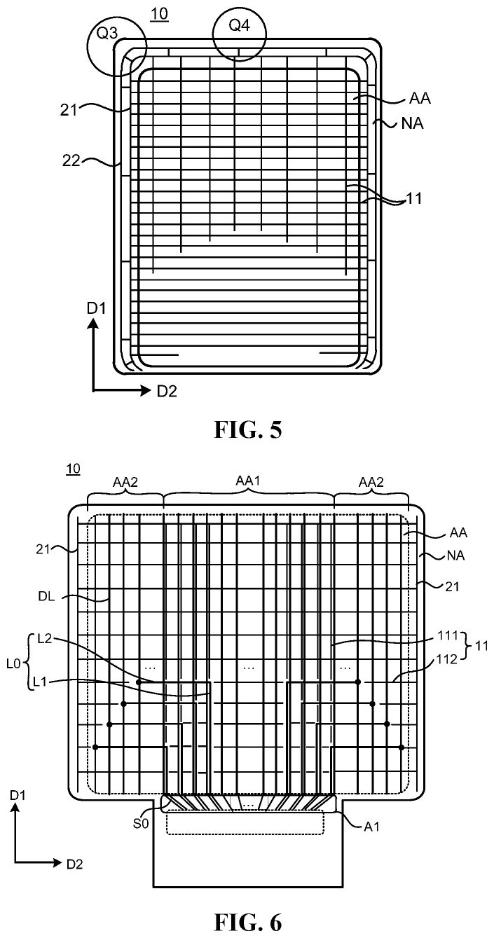

It is to be noted that FIG. 1 exemplarily illustrates only that the auxiliary power lines 11 extend in the lateral direction and that the first power bus 21 and the first power main body 22 are located in the non-display region NA on the same side of the display region AA. Orientations shown in FIG. 1 are taken as an example which illustrates only that the first power bus 21 and the first power main body 22 are located in the non-display region NA on the left. In other embodiments, the first power bus 21 and the first power main body 22 may also be located in the non-display region NA on other sides. For example, in the display panel 10 shown in FIG. 4, the first power bus 21 and the first power main body 22 may also be located in the non-display region NA on the right. Alternatively, in the display panel 10 shown in FIG. 5, the first power bus 21 and the first power main body 22 may also be located in the non-display region NA on the upper side. With the display panel 10 shown in FIG. 5 as an example, the auxiliary power lines 11 in the display region AA may also extend in the longitudinal direction. Accordingly, the first power bus 21 and the first power main body 22 may also extend in the lateral direction. In other embodiments, the auxiliary power lines 11 in the display region AA may also extend in other directions in the display panel 10 and are not limited here. The first power bus 21 and the first power main body 22 may include a straight line portion and may also include an arc line portion. The straight line portion may be, for example, wires in the left region in FIG. 1, wires in the right region in FIG. 4, or wires in the upper region in FIG. 5. The arc line portion may be, for example, wires in the region Q1 region in FIG. 1 or wires in a region Q3 in FIG. 5.

Exemplarily, the first power bus 21 is configured to supply power signals. The width of the first power bus 21 is equal to or equivalent to the width of another power signal line in the non-display region NA of the display panel 10 (for example, the difference is within ±20%). Exemplarily, other power signal lines in the non-display region NA may include at least one of a reference power signal line for supplying Vref signals in the display panel, a second power signal line for supplying PVDD signals in the display panel, a high-potential signal line for supplying VGH signals in the display panel, or a low-potential signal line for supplying VGL signals in the display panel.

Exemplarily, the width of the first power main body 22 needs to meet the requirements of the electrical connection for wire change and helps form a barrier wall structure in the non-display region to avoid the invasion of external water and oxygen. The specific value thereof is not limited here.

It is to be noted that FIGS. 1 to 5 exemplarily illustrate only the relative position relationship between the display region AA and the non-display region NA as well as the position relationship and connection relationship between the auxiliary power lines 11, the first power bus 21, and the first power main body 22 in the display region AA and the non-display region NA and are not to limit the number and wiring of the auxiliary power lines 11, the first power bus 21, and the first power main body 22.

The display panel 10 provided in embodiments of the present disclosure includes the display region AA and the non-display region NA at least partially surrounding the display region AA. The display region AA includes the auxiliary power lines 11. The non-display region NA includes the first power main body 22 and the first power bus 21. The auxiliary power lines 11 are electrically connected to the first power main body 22 through the first power bus 21. Accordingly, the auxiliary power lines 11 are disposed in the display region AA and electrically connected to the first power main body 22 through the first power bus 21 disposed in the non-display region NA. The first power main body 22 is used to supply a power voltage to the auxiliary power lines 11 in the display region AA through the first power bus 21. Accordingly, a new structure of the display panel 10 is provided with high connection reliability, balancing voltage drops at different positions in the display panel 10 and improving the display uniformity of the display panel 10.

In some embodiments, as shown in FIG. 6, the non-display region NA in the display panel 10 includes a fan-out region A1 disposed on one side of the display region AA in a first direction D1. With orientations shown in FIG. 6 as an example, the fan-out region A1 is located on the lower side of the display region AA. The display region AA includes a first display region AA1 and a second display region AA2. The second display region AA2 is disposed on at least one side of the first display region AA1 in a second direction D2. With orientations shown in FIG. 6 as an example, the second display region AA2 is located on the left side of the first display region AA1 and the right side of the first display region AA1. In other embodiments, the second display region AA2 may also be located on the left side of the first display region AA1 or the right side of the first display region AA1, which is not limited here. The second direction D2 intersects the first direction D1. Exemplarily, the first direction D1 may be perpendicular to the second direction D2.

The fan-out region includes a plurality of fan-out wires S0. The first display region AA1 and the second display region AA2 each include a plurality of data lines DL extending in the first direction D1 and arranged in the second direction D2. A data line DL is connected to a fan-out wire S0. Here a data line DL in the second display region AA2 is connected to a respective fan-out wire S0 through a connection wire L0. The connection wire L0 is located in the display region AA and the connection wire L0 includes a first connection line segment L1 extending in the first direction D1 and a second connection line segment L2 extending in the second direction D2. The first connection line segment L1 is electrically connected to the respective fan-out wire S0. The second connection line segment L2 is electrically connected to the data line DL in the second display region AA2. The auxiliary power lines 11 include at least one of a first auxiliary power line 111 extending in the first direction D1 or a second auxiliary power line 112 extending in the second direction D2. The first auxiliary power line 111 is disposed in the same layer as the first connection line segment L1 and insulated from the first connection line segment L1 and the second connection line segment L2. The second auxiliary power line 112 is disposed in the same layer as the second connection line segment L2 and insulated from the first connection line segment L1 and the second connection line segment L2.

With the structure shown in FIG. 6 as an example, the first display region AA1 may be located in the middle region of the display panel 10, and the second display region AA2 may be located on both sides of the first display region AA1. Accordingly, the auxiliary power lines 11 and connection lines L0 of the display panel 10 in the display region AA can be designed to be symmetrical left and right, thereby reducing wiring difficulty.

A data line DL in the first display region AA1 is electrically connected to a fan-out wire S0 in the fan-out region A1 directly. The data line DL in the second display region AA2 is electrically connected to the respective fan-out wire S0 in the fan-out region A1 through the second connection line segment L2 extending in the second direction D2 and the first connection line segment L1 extending in the first direction D1 included in the connection wire L0. With this arrangement, no fan-out wires need to be arranged at the lower left bezel of the display panel 10 and/or the lower right bezel of the display panel 10 so that space is provided for the bezel of the display panel 10 and the display device to be compressed, facilitating the design of the narrow bezel of the display panel 10 and the display device and facilitating the full screen.

The auxiliary power lines 11 and the connection wires L0 may be at least partially disposed in the same layer and electrically insulated so that the auxiliary power lines 11 are disposed in at least part of the layers where the connection wires L0 are located, making full use of wires in the layers and improving the wiring uniformity in the layers.

The auxiliary power lines 11 may include the first auxiliary power line 111 and the second auxiliary power line 112 whose extension directions intersect each other. The first auxiliary power line 111 and the first connection line segment L1 are disposed in the same layer and extend in the first direction D1. The first auxiliary power line 111 and the first connection line segment L1 may be electrically insulated through a gap between the first auxiliary power line 111 and the first connection line segment L1. The first auxiliary power line 111 is also electrically insulated from the second connection line segment L2. The second auxiliary power line 112 and the second connection line segment L2 are disposed in the same layer and extend in the second direction D2. The second auxiliary power line 112 and the second connection line segment L2 may be electrically insulated through a gap between the second auxiliary power line 112 and the second connection line segment L2. The second auxiliary power line 112 is also insulated from the first connection line segment L1. The first auxiliary power line 111 is disposed in the layer where the first connection line segment L1 is located, and/or the second auxiliary power line 112 is disposed in the layer where the second connection line segment L2 is located, improving the uniformity of the wiring density of the layer where the first connection line segment L1 and/or the second connection line segment L2 is located, thereby helping alleviate the phenomenon of display non-uniformity due to the non-uniformity of wiring density, and improving the display uniformity of the display panel 10.

It is to be noted that FIG. 6 exemplarily illustrates only the connection relationship between the data lines DL, the fan-out wires S0, the connection wires L0 and the auxiliary power lines 11 included in the display panel, which are described above by way of example. The number of data lines DL, the number of fan-out wires S0, the number of connection wires L0 and the number of auxiliary power lines 11 actually included in the display panel 10 are not limited.

It is to be understood that FIG. 6 exemplarily illustrates only the structure of a lower bezel included in the display panel 10, and the structure of an upper bezel may be any structure known to those skilled in the art, which is neither repeated nor limited here.

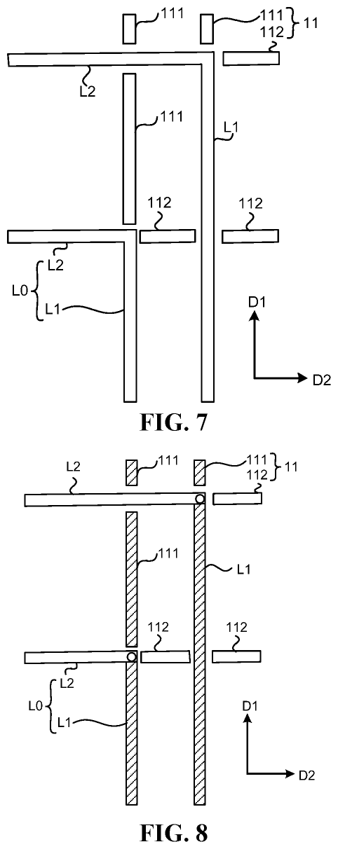

In some embodiments, as shown in FIG. 7, first connection line segments L1 in the connection wires L0 are disposed in the same layer as second connection line segments L2 in the connection wires L0. First auxiliary power lines 111 in the auxiliary power lines 11 are disposed in the same layer as second auxiliary power lines 112 in the auxiliary power lines 11.

The first connection line segments L1 in the connection wires L0 are disposed in the same layer as the second connection line segments L2 in the connection wires L0. In conjunction with the preceding description, the first auxiliary power lines 111 are disposed in the same layer as the first connection line segments L1, and the second auxiliary power lines 112 are disposed in the same layer as the second connection line segments L2. Therefore, the first connection line segments L1, the second connection line segments L2, the first auxiliary power lines 111, and the second auxiliary power lines 112 are disposed in the same layer. With this arrangement, the first connection line segments L1, the second connection line segments L2, the first auxiliary power lines 111, and the second auxiliary power lines 112 can be formed in the same layer by using a patterning technique (for example, a mask etching technique), helping simplify the steps of the technique, helping simplify the total number of layers in the display panel 10, and implementing a thin and light design.

In some embodiments, as shown in FIG. 8, the first connection line segments L1 in the connection wires L0 are disposed in the same layer, the second connection line segments L2 in the connection wires L0 are disposed in the same layer, and the first connection line segments L1 and the second connection line segments L2 are disposed in different layers. Accordingly, the first auxiliary power lines 111 in the auxiliary power lines 11 are disposed in the same layer, the second auxiliary power lines 112 in the auxiliary power lines 11 are disposed in the same layer, and the first auxiliary power lines 111 and the second auxiliary power lines 112 are disposed in different layers.

The first connection line segments L1 in the connection wires L0 and the first auxiliary power lines 111 in the auxiliary power lines 11 is disposed in the same layer. The extension direction of the first auxiliary power lines 111 are the same as the extension direction of the first connection line segments L1. The second connection line segments L2 in the connection wires L0 and the second auxiliary power lines 112 in the auxiliary power lines 11 are disposed in the same layer. The extension direction of the second auxiliary lines 112 is the same as the extension direction of the second connection line segments L2. Such an arrangement helps improve the uniformity of the wiring density of layers where the first connection line segments L1 and the second connection line segments L2 are located, thereby helping alleviate the phenomenon of display non-uniformity due to the non-uniformity of wiring density and thus improving the display uniformity of the display panel.

Moreover, the first connection line segments L1 in all the connection wires L0 and the first auxiliary power lines 111 in all the auxiliary power lines 11 are disposed in the same layer, and the second connection line segments L2 in all the connection wires L0 and the second auxiliary power lines 112 in all the auxiliary power lines 11 are disposed in another layer. In this case, the first connection line segments L1 and the first auxiliary power lines 111 extending in the first direction D1 are disposed in one of the two layers, and the second connection line segments L2 and the second auxiliary power lines 112 extending in the second direction D2 are disposed in the other layer. Wires in a single layer have the same extension direction, simplifying the patterning in the single layer, reducing technique difficulty, and improving the yield.

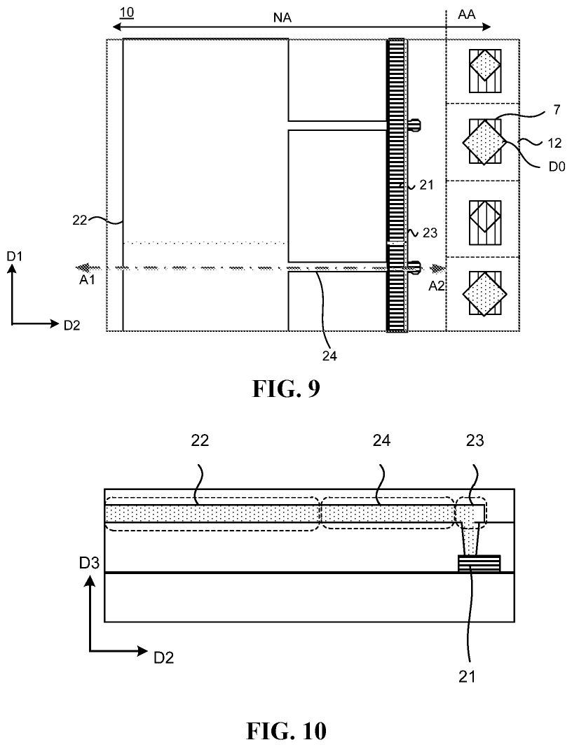

In some embodiments, as shown in FIGS. 9 and 10, the non-display region NA further includes a first connection structure 23 extending in at least one direction of the first direction D1 or the second direction D2. The first connection structure 23 is disposed on one side of the first power main body 22 facing towards the display region AA. The first power bus 21 is electrically connected to the first power main body 22 through the first connection structure 23.

The extension direction of the first connection structure 23 is the same as the extension direction of the first power bus 21. In some embodiments, the shape of the first connection structure 23 is similar to the shape of the first power bus 21. Exemplarily, the first power bus 21 is a strip-shaped structure, and the first connection structure may also be a strip-shaped structure. With orientations shown in FIG. 9 as an example, the first connection structure 23 extends in the first direction D1. It is to be understood that FIG. 9 illustrates a structure that is in the non-display region NA located on the left side of the display region AA in the display panel 10. In other embodiments, in the non-display region NA located on the upper side of the display region AA in the display panel 10, the first power bus 21 and the first connection structure 23 may also each extend in the second direction D2.

In the non-display region NA on any side of the display region AA in the display panel 10, the first connection structure 23 is disposed on one side of the first power main body 22 facing towards the display region AA. That is, the first connection structure 23 is located between the first power main body 22 and the display region AA. The first connection structure 23 is electrically connected to the first power main body 22 and the first power bus 21, thereby implementing the electrical connection between the first power main body 22 and the first power bus 21.

Exemplarily, as shown in FIG. 10, the first power bus 21 and the first connection structure 23 are disposed in different layers and may be connected through a via hole. The first connection structure 23 and the first power main body 22 may be disposed in the same layer and may be connected via an intra-layer structure (for example, a second connection structure 24), which is illustrated hereinafter in conjunction with a layer structure.

In some embodiments, as shown in FIG. 9, the first connection structure 23 is a continuous strip-shaped structure and is electrically connected to the first power main body 22.

For the entire display panel 10, the first connection structure 23 may be a continuous, integral strip-shaped structure. In this structure, the first power main body 22 may be an integral structure or a disconnected, split structure, all of which can transmit the same power signal, thereby facilitating the flexible design of the first power main body 22.

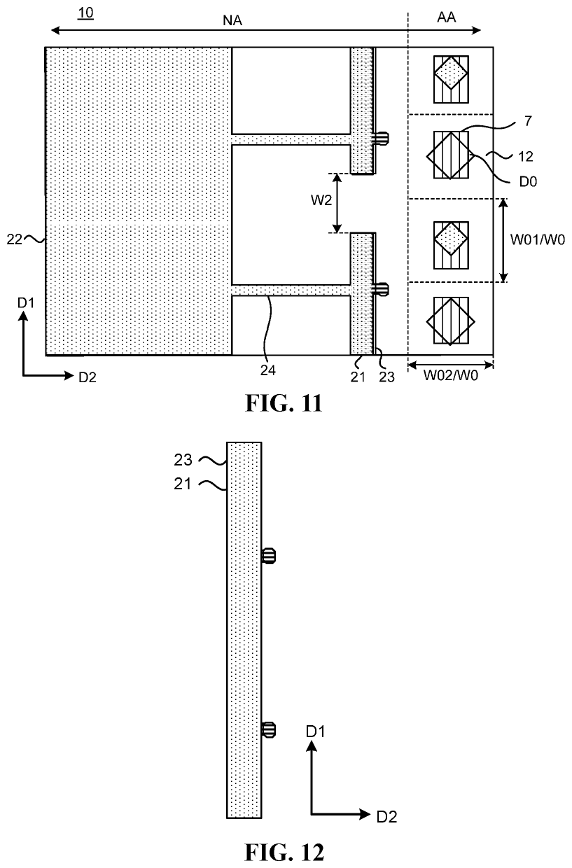

In some embodiments, as shown in FIG. 11, the display region AA further includes the sub-pixels 12 arranged in an array, that is, pixel driving circuits 7 arranged in an array and light-emitting elements DO (e.g. each of which includes an anode, a light-emitting material, and a cathode) arranged in an array. The first connection structure 23 is disconnected at a second preset distance W2. The second preset distance W2 is greater than or equal to the width W0 of 1/10 sub-pixels 12.

The width of a single sub-pixel 12 may be the width between the same structures having the same function in the display panel 10. Exemplarily the width of a gap between first connection structures 23 (that is, the second preset distance W2) is set with reference to the width of a sub-pixel 12. As shown in FIG. 11, a first connection structure 23 extending in the first direction D1 may be understood as the first connection structure 23 in the non-display region NA located on the left side of the display region or the right side of the display region AA in the preceding description. The width in the first direction D1 may be used to define the width W01 of a sub-pixel 12 for reference. A first connection structure 23 extending in the second direction D2 may be understood as the first connection structure 23 in the non-display region NA located on the upper side of the display region AA in the preceding description. The width in the second direction D2 may be used to define the width W02 of a sub-pixel 12 for reference.

In the first direction D1, the width may be the width between two scan lines having the same function, such as the distance between two scan lines controlling data writing in adjacent rows (for example, second scan signal lines Scan2 hereinafter), the distance between two scan lines controlling light emission in adjacent rows (for example, light emission control signal lines Emit hereinafter), or the distance between two scan lines controlling the gate reset (or anode reset) of drive transistors in adjacent rows. In the second direction D2, the width may be the width between two data lines having the same function. In other embodiments, the width may also be defined by using wires or other structures having the same function in the display panel 10, which is neither repeated nor limited here.

The difference between these embodiments of the present disclosure and the preceding embodiments lies in that the first connection structure 23 is not a continuous, integral structure but is disconnected into at least two structures. That is, two or more first connection structures 23 may be provided. The gap between two adjacent first connection structures 23 is the second preset distance W2. The gap may be understood as the missing portion between two first connection structures 23, as shown in FIG. 11. In other embodiments, the gap between two first connection structures 23 may also be defined by correspondingly-identical points in two first connection structures 23, for example, start points in two first connection structures 23 in the same extension direction, end points in two first connection structures 23 in the same extension direction, or any intermediate points in two first connection structures 23 in the same extension direction, which is not limited here. In this structure, the first power main body 22 may be an integral structure or a disconnected, split structure. A disconnection point of the first power main body 22 is misaligned with a disconnection point of each first connection structure 23 so as to guarantee that they serve as a whole and can supply power signals to the auxiliary power lines in the display region AA. The structure of the first power main body 22 is described exemplarily hereinafter.

In embodiments of the present disclosure, the second preset distance W2 is greater than or equal to the width W0 of 1/10 sub-pixels 12. For example, the second preset distance W2 may be that W2= 1/10 W0, that W2=⅕ W0, that W2=½ W0, that W2=W0, that W2=2 W0, or that W2=3 W0, that W2=4 W0 or may be the width W0 of more sub-pixels 12, which may be set based on the wiring requirements of the display panel 10 and is not limited here.

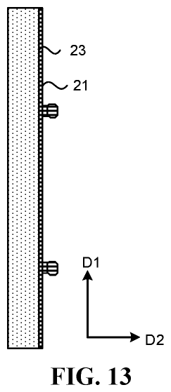

In some embodiments, as shown in FIG. 12 or 13, the vertical projection of the first power bus 21 on a plane where the first connection structure 23 is located overlaps at least the first connection structure 23. The ratio of the overlapping area to the area of the first connection structure 23 is P, where 50%≤P≤100%.

The plane where the first connection structure 23 is located is a plane parallel to the substrate 4. The vertical projection of the first power bus 21 on the plane overlaps the vertical projection of the first connection structure 23 on the plane. The ratio of the overlapping area to the area of the first connection structure 23 is in the range of [50%, 100%]. A greater P value indicates that the overlapping area of the first power bus 21 and the first connection structure 23 is larger, that the large-area electrical connection is better facilitated, and thus that the electrical connection between the first power bus 21 and the first connection structure 23 has better stability.

The first power bus 21 and the first connection structure 23 are electrically connected through a via hole in the overlapping area. The first connection structure 23 is a disconnected structure. In this case, the corresponding first power bus 21 may be disconnected in response to the disconnection of the first connection structure 23 or may be continuous as a whole, which is not limited here. In embodiments of the present disclosure, the ratio of the overlapping area of the first power bus 21 and the first connection structure 23 to the area of the first connection structure 23 is set so that the overlapping area is relatively large, facilitating the large-area electrical connection and thereby making the electrical connection between the first power bus 21 and the first connection structure 23 have relatively sound stability.

Exemplarily, as shown in FIG. 12, the projection area of the first connection structure 23 is greater than the projection area of the first power bus 21. Exemplarily, the vertical projection of the first connection structure 23 may totally cover the vertical projection of the first power bus 21. In this case, the overlapping area of the first power bus 21 and the first connection structure 23 may be understood as the area of the strip-shaped first power bus 21. In this case, the first connection structure 23 still has a region that does not overlap the first power bus 21. In this case, the ratio P of the overlapping area to the area of the first connection structure 23 is less than 100% and is greater than or equal to 50%. The entire area of the first power bus 21 may be used to implement the electrical connection, resulting in relatively sound stability.

In other embodiments, the first power bus 21 may also have a region that does not overlap the first connection structure 23. That is, the vertical projection of the first power bus 21 and the vertical projection of the first connection structure 23 overlap each other with a misaligning region existing. In this case, at least part of the overlapping region of the first power bus 21 and the first connection structure 23 may be used to implement the electrical connection between the first power bus 21 and the first connection structure 23, as shown in FIG. 13.

It is to be noted that FIGS. 12 and 13 illustrate only structures possibly existing in a partial range in the display panel. At least one preceding structure may exist in the entire display panel.

In other embodiments, the vertical projection of the first connection structure 23 on the plane where the first connection structure 23 is located may totally overlap the vertical projection of the first power bus 21 on the plane where the first connection structure 23 is located. The first connection structure 23 is located in the vertical projection of the first power bus 21 and totally covers the vertical projection of the first power bus 21. In this case, the overlapping area is the area of the first connection structure 23. Accordingly, the ratio P of the overlapping area to the area of the first connection structure 23 is equal to 100%. The entire-area electrical connection is used to guarantee relatively sound connection stability.

In some embodiments, as shown in any one of FIGS. 9 to 11, the non-display region NA further includes a second connection structure 24. The second connection structure 24 is located between the first connection structure 23 and the first power main body 22. The first connection structure 23 is electrically connected to the first power main body 22 through the second connection structure 24.

Exemplarily, with the non-display region NA located on the left side of the display region AA in the display panel 10 shown in any one of FIGS. 9 to 11 as an example, the first power main body 22 and the first power bus 21 each extends in the first direction D1. The first connection structure 23 also extends in the first direction D1. In the thickness direction of the display panel 10 (that is, the direction perpendicular to the plane parallel to the substrate 4), the first connection structure 23 overlaps the first power bus 21 to implement the electrical connection between the first power bus 21 and the first connection structure 23, and the second connection structure 24 is located between the first connection structure 23 and the first power main body 22 to implement the electrical connection between the first power main body 22 and the first connection structure 23.

Exemplarily, at least one second connection structure 24 is provided. Two second connection structures 24 in a partial region in the drawings are used as an example for exemplary description. The second connection structures 24 extend in the second direction D2 and are arranged in the first direction D1. With this arrangement, the first power main body 22 is electrically connected to the first connection structure 23 through the second connection structures 24 so as to be electrically connected to the first power bus 21.

In other embodiments, the extension direction of the second connection structure 24 varies with the extension direction of the first power main body 22 (or the first connection structure 23). The extension direction of the second connection structure 24 intersects the extension direction of the first power main body 22 and the extension direction of the first connection structure 23 to implement the electrical connection between the first power main body 22 and the first connection structure 23.

Exemplarily, referring to FIG. 4, with the non-display region NA located on the upper side of the display region AA in the display panel 10 as an example, the first connection structure 23 and the first power main body 22 each extend in the second direction D2. In this case, the second connection structure 24 may extend in the first direction D1 to implement the electrical connection between the first power main body 22 and the first connection structure 23.

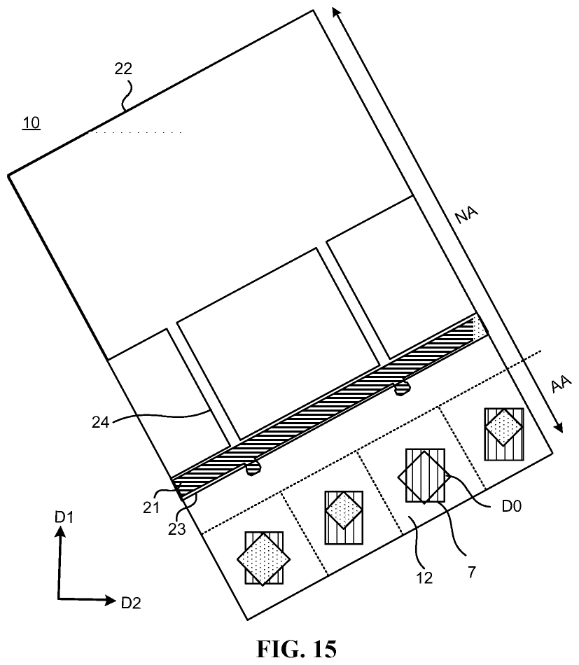

In other embodiments, the second connection structure 24 may also extend in other directions in the non-display region NA located on other orientations of the display region AA. As shown in FIG. 15, the extension direction of the second connection structure 24 may be in the plane parallel to the substrate 4 and intersects both the first direction D1 and the second direction D2 as long as the electrical connection between the first power main body 22 and the first connection structure 23 can be implemented, which is not limited here.

In some embodiments, as shown in FIG. 16, the non-display region NA further includes reset signal lines 25 and a shift register circuit 26. The reset signal lines 25 extend in the first direction D1 and are arranged in the second direction D2. At least one reset signal line 25 is located between the first power bus 21 and the first power main body 22. The shift register circuit 26 is disposed on one side of the reset signal lines 25 facing away from the display region AA.

The reset signal lines 25 are configured to transmit reset signals/reference power signals/reference voltage signals to avoid the effect of the display image in the previous frame on the display image in the current frame, guaranteeing relatively sound image display quality. The magnitude of a reset signal voltage may be set based on display requirements, which is neither repeated nor limited here.

At least one reset signal line 25 is provided and extends in the first direction. When two or more reset signal lines 25 are provided, the reset signal lines 25 are also arranged in the second direction D2. Exemplarily, FIG. 16 exemplarily illustrates a case in which the non-display region NA includes two reset signal lines 25. The two reset signal lines 25 extend in the first direction D1 and are arranged in the second direction D2. The two reset signal lines 25 are configured to reset transistors and light-emitting elements separately, which is not limited here. In other embodiments, one reset signal line 25 may be provided. In this case, the reset signal line 25 is disposed between the first power bus 21 and the first power main body 22. In this embodiment, two or more reset signal lines 25 are provided. At least one of the reset signal lines 25 is disposed between the first power bus 21 and the first power main body 22, which is not limited here.

It is to be understood that FIG. 16 illustrates only a region where the shift register circuit 26 is located. The shift register circuit 26 is disposed on one side of the reset signal lines 25 facing away from the display region AA. Compared with the reset signal lines 25, the shift register circuit 26 is further away from the display region AA. The shift register circuit 26 may use any one circuit structure known to those skilled in the art to implement the shift register function so as to supply timing logic control signals to the display region AA, which is not limited here.

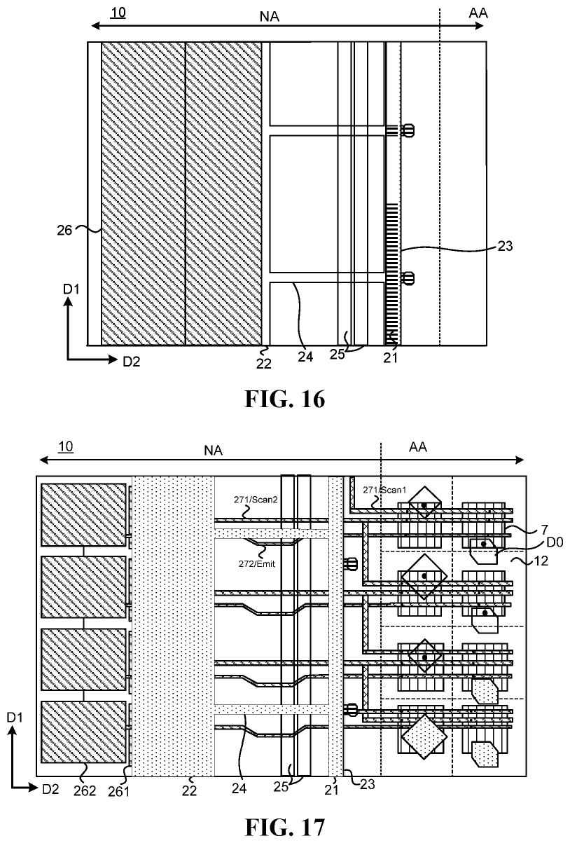

In some embodiments, as shown in FIG. 16 or 17, the shift register circuit 26 overlaps the first power main body 22 in the thickness direction of the display panel 10.

The thickness direction of the display panel 10 is the direction perpendicular to the plane parallel to the substrate 4. The shift register circuit 26 overlaps the first power main body 22 in the thickness direction of the display panel 10, that is, the vertical projection of the shift register circuit 26 on the plane parallel to the substrate 4 overlaps the vertical projection of the first power main body 22 on the plane parallel to the substrate 4. Exemplarily, the vertical projection of the first power main body 22 on the plane is, for example, partially or entirely, located in the vertical projection of the shift register circuit 26 on the plane, which is not limited here.

In embodiments of the present disclosure, the arrangement in which the shift register circuit 26 overlaps the first power main body 22 in the thickness direction of the display panel 10 helps reduce the width of the bezel, facilitate the design of the narrow bezel, and thus facilitate the full screen.

In some embodiments, as shown in FIGS. 16 and 17, the shift register circuit 26 includes a scan driving signal circuit 261 and a light emission driving signal circuit 262. The scan driving signal circuit 261 is connected to a sub-pixel 12 in the display region AA through a first transmission line 271. The light emission driving signal circuit 262 is connected to the sub-pixel in the display region AA through a second transmission line 272. The second connection structure 24 overlaps at least one of the first transmission line 271 or the second transmission line 272 in the thickness direction of the display panel 10.

The sub-pixel 12 includes a pixel driving circuit 7. The pixel driving circuit 7 is connected to the scan driving signal circuit 261 through the first transmission line 271, connected to the light emission driving signal circuit 262 through the second transmission line 272, and connected to an anode of a light-emitting element. FIG. 17 illustrates the anode with a diamond disposed in the same layer as the first power main body 22.

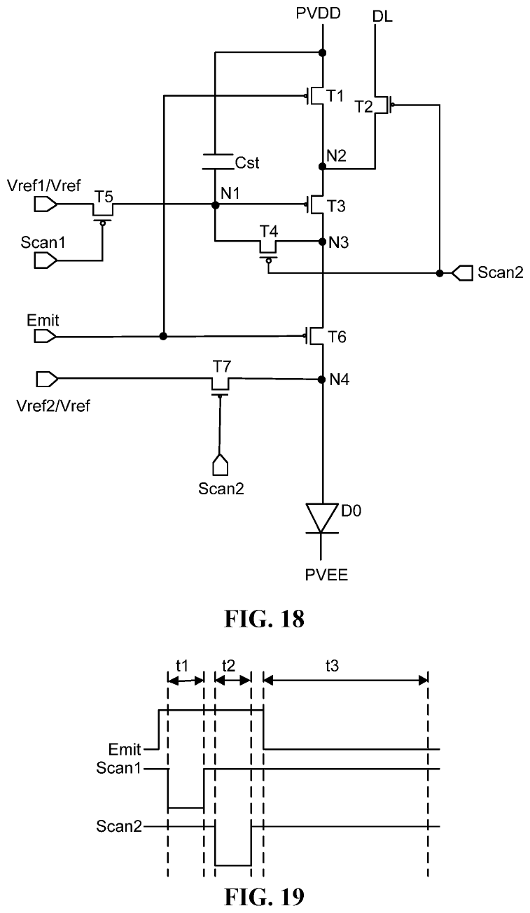

The first transmission line 271 and the second transmission line 272 are connected to the pixel driving circuit 7 in the sub-pixel 12 separately and transmit scan signals (for example, Scan1 and Scan2 in FIGS. 18 and 19) and light emission control signals (for example, Emit in FIGS. 18 and 19) respectively to selectively drive the light-emitting element DO to emit light and present a display image. The first transmission line 271 and the second transmission line 272 are connected to the pixel driving circuit 7 in any manner known to those skilled in the art, which is neither repeated nor limited here.

The scan driving signal circuit 261 is connected to the sub-pixel 12 in the display region AA through the first transmission line 271 to enable the scan driving signal circuit 261 to transmit the scan signals to the sub-pixel 12 in the display region AA. The light emission driving signal circuit 262 is connected to the sub-pixel 12 in the display region AA through the second transmission line 272 to enable the light emission driving signal circuit 26 to transmit the light emission control signals to the sub-pixel 12 in the display region AA. Therefore, the light-emitting element DO is selectively controlled to emit light. Exemplarily, for a single pixel driving circuit, two first transmission lines 271 may be provided for transmitting first scan signals and second scan signals, as shown in FIGS. 17 and 18.

Exemplarily, FIG. 18 illustrates a diagram of the electronic element structure of the pixel driving circuit. The pixel driving circuit is a 7TIC circuit including seven transistors and one storage capacitor. Specifically, in the pixel driving circuit, a control terminal of a third transistor T3 is electrically connected to a first node N1. A first terminal of the third transistor T3 is electrically connected to a second node N2. A second terminal of the third transistor T3 is electrically connected to a third node N3. A control terminal of the first transistor T1 is electrically connected to a light emission control signal line Emit. A first terminal of the first transistor T1 is electrically connected to a second power signal line PVDD. A control terminal of a second transistor T2 is electrically connected to a second scan signal line Scan2. A first terminal of the second transistor T2 is electrically connected to a data line DL. A second terminal of the first transistor T1 and a second terminal of the second transistor T2 are each electrically connected to the second node N2. A control terminal of a fourth transistor T4 is electrically connected to the second scan signal line Scan2. A first terminal of the fourth transistor T4 is electrically connected to the third node N3. A second terminal of the fourth transistor T4 is electrically connected to the first node N1. A control terminal of a fifth transistor T5 is electrically connected to a first scan signal line Scan1. A first terminal of the fifth transistor T5 is electrically connected to a reference voltage signal line Vref. A second terminal of the fifth transistor T5 is electrically connected to the first node N1. A control terminal of a sixth transistor T6 is electrically connected to the light emission control signal line Emit. A first terminal of the sixth transistor T6 is electrically connected to the third node N3. A second terminal of the sixth transistor T6 is electrically connected to a fourth node N4. A control terminal of a seventh transistor T7 is electrically connected to a second scan signal line Scan2. A first terminal of the seventh transistor T7 is electrically connected to a reference voltage signal line Vref. A second terminal of the seventh transistor T7 is electrically connected to the fourth node N4. A first electrode of the light-emitting element DO is electrically connected to the fourth node N4. A second electrode of the light-emitting element DO is electrically connected to a first power signal line PVEE. A first plate of the storage capacitor Cst is electrically connected to the second power signal line PVDD. A second plate of the storage capacitor Cst is electrically connected to the first node N1.

Exemplarily, FIG. 19 illustrates the drive timing graph of a pixel driving circuit. When the pixel driving circuit 7 operates, the operating process of the pixel driving circuit 7 includes a reset stage t1, a charging stage t2, and a light emission stage t3.

In the first stage t1, the first scan signal line Scan1 controls the fifth transistor T5. A reference voltage supplied by the reference voltage signal line Vref electrically connected to the fifth transistor T5 resets the first node N1 through the fifth transistor T5.

In a data write and threshold compensation stage t2, the second scan signal line Scan2 electrically connected to the second transistor T2 and the fourth transistor T4 controls the second transistor T2 and the fourth transistor T4 to turn on. A data voltage Vdata supplied by the data line DL is written to the second node N2 through the second transistor T2. In this stage, the third transistor T3 is turned on. The potential of the first node N1 varies constantly until the potential VN1 of the first node N1 varies to that VN1=Vdata−|Vth|. Vdata denotes the data voltage supplied by the data line DL. Vth denotes a threshold voltage of the third transistor T3. Moreover, the second scan signal line Scan2 electrically connected to the seventh transistor T7 controls the seventh transistor T7 to turn on. A reference voltage supplied by the reference voltage signal line Vref electrically connected to the seventh transistor T7 resets the fourth node N4 through the seventh transistor T7.

In the light emission stage t3, the first transistor T1, the sixth transistor T6, and the third transistor T3 are turned on. Under the action of a first power voltage supplied by the second power signal line PVDD and a second power voltage supplied by the first power signal line PVEE, a current path between the second power signal line PVDD and the first power signal line PVEE is turned on, and the light-emitting element DO electrically connected to the pixel driving circuit 7 lights up.

In embodiments of the present disclosure, different pixel driving circuits 7 may require the same first power voltage, the same second power voltage, and the same reference voltage when working. That is, the first power voltage transmitted by the second power signal line PVDD, the second power voltage transmitted by the first power signal line PVEE, and each reference voltage transmitted by each reference voltage signal line Vref may be common signals shared by multiple pixel driving circuits 7.

In embodiments of the present disclosure, the reset of the gate of the third transistor T3 and the reset of the light-emitting element DO may use the same reference voltage Vref and may also use different reference voltages which are distinguished by a first reference voltage Vref1 and a second reference voltage Vref2. The first reference voltage Vref1 is configured to reset the gate of the third transistor T3. The second reference voltage Vref2 may be configured to reset the light-emitting element DO.

In embodiments of the present disclosure, the fourth transistor T4 and the fifth transistor T5 may be each an oxide transistor to reduce leakage currents. The oxide may be, for example, Indium Gallium Zinc Oxide (IGZO). Other transistors may be each a low temperature poly-silicon (LTPS) transistor.

In embodiments of the present disclosure, the fourth transistor T4 and the fifth transistor T5 may be each a dual-gate transistor to reduce leakage currents and improve display effect.

In other embodiments, the pixel driving circuit may also use other circuit structures, which is not limited here.

In embodiments of the present disclosure, in the thickness direction of the display panel 10, the second connection structure 24 may overlap only the first transmission line 271, only the second transmission line 272, or both the first transmission line 271 and the second transmission line 272, thereby reducing the planar area occupied by wires, that is, the area in the plane parallel to the substrate 4, and facilitating the design of the narrow bezel and miniaturization of the display panel 10.

It is to be understood that FIG. 17 exemplarily illustrates only the spatial position of the scan driving signal circuit 261 and the light emission driving signal circuit 262. The structure thereof may be any structure known to those skilled in the art, which is neither repeated nor limited here.

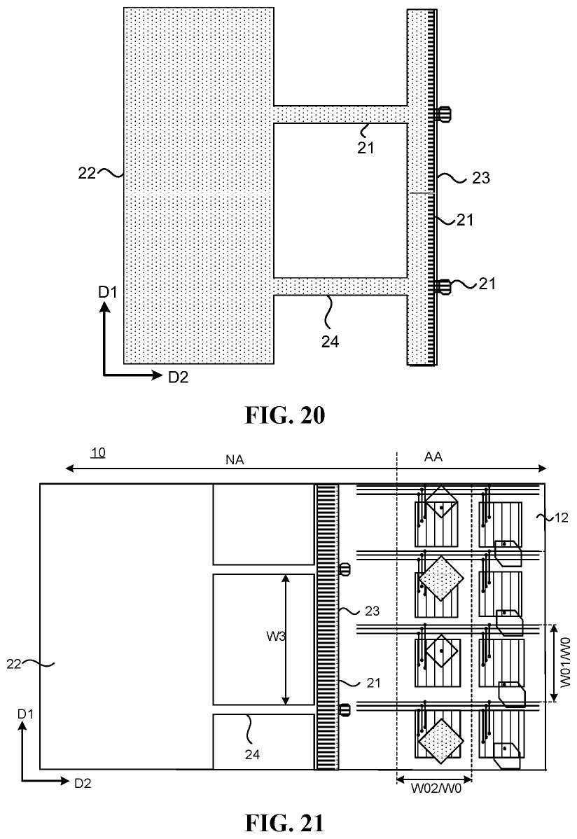

In some embodiments, as shown in FIG. 20, the first power bus 21 further overlaps the second connection structure 24 in the thickness direction of the display panel.

With the non-display region AA located on the left side of the display region AA as an example, at least part of the first power bus 21 also extends in the second direction D2. Moreover, the part of the first power bus 21 extending in the second direction D2 overlaps the second connection structure 24 in the thickness direction of the display panel. With this arrangement, the total connection area between the first power bus 21 and the first connection structure 23 and second connection structure 24 is increased, thereby improving the stability of the electrical connection between the first power bus 21 and the first connection structure 23 and second connection structure 24 and thus improving the stability of the electrical connection between the first power bus 21 and the first power main body 22.

In other embodiments, the first power bus 21 in the non-display region AA located on other orientations of the display region AA may also extend in the extension direction of the second connection structure 24 so as to overlap the second connection structure 24, increasing the area of the electrical connection and thereby improving connection stability.

In some embodiments, as shown in FIG. 21, the display region further includes the sub-pixels 12 arranged in an array. the distance W3 between two adjacent second connection structures 24 in the arrangement direction of the second connection structures 24, for example, the first direction D1 in FIG. 21, is greater than or equal to the width W0 of a single sub-pixel 12 in the arrangement direction.

FIG. 21 exemplarily illustrates three types of signal lines extending in the second direction D2. For each sub-pixel, the three different types of signal lines may be configured to transmit first scan signals, second scan signals, and light emission control signals. The width of a sub-pixel is marked with signal lines with consistent relative positions for transmitting the same type of signals. The width of a single sub-pixel may be understood with reference to the preceding description, which is not repeated here.

Two or more second connection structures 24 are provided and arranged in the extension direction of the first power bus 21 (or the first connection structure 23 or the first power main body 22). In the arrangement direction of the second connection structures 24, the distance W3 between two adjacent second connection structures 24 is greater than or equal to the width W0 of a single sub-pixel 12.

Exemplarily, the distance W3 between two adjacent second connection structures 24 may be the gap between two second connection structures 24, that is, the shortest distance between two adjacent second connection structures 24, as shown in FIG. 21.

In other embodiments, the distance W3 may also be the distance between corresponding positions of two second connection structures 24, for example, the distance between start points in two second connection structures 24 in the arrangement direction, end points in two second connection structures 24 in the arrangement direction, or any intermediate points in two second connection structures 24 in the arrangement direction, which is not limited here.

In embodiments of the present disclosure, the distance W3 between two adjacent second connection structures 24 may be the width W0 of one, two, three, or more sub-pixels 12, which is not limited here.

In embodiments of the present disclosure, the second connection structures 24 spaced apart facilitates the electrical connection between the first connection structure 23 and the first power main body 22. The second connection structures 24 may be strip-shaped structures, line-shaped structures, or structures in other shapes, thereby improving electrostatic conduction. An exemplary description is made hereinafter in combination with a pixel defining layer.

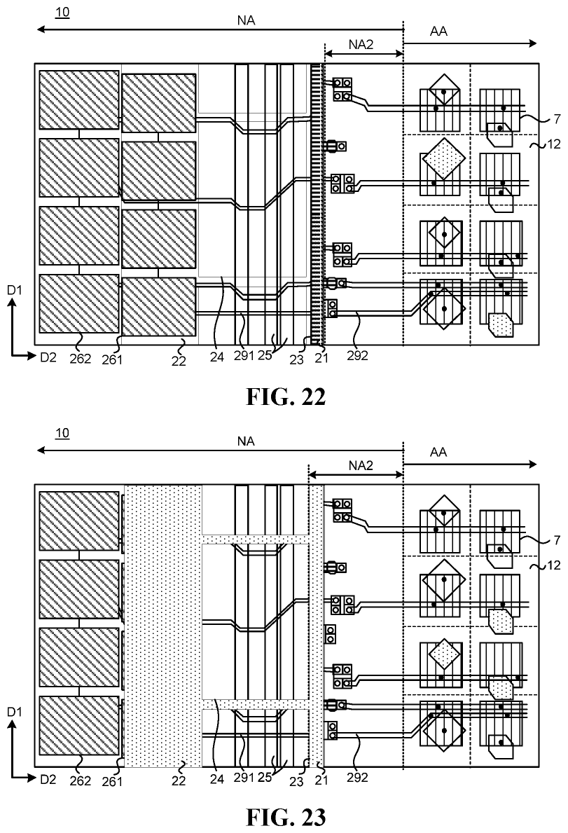

In some embodiments, as shown in FIG. 22, the non-display region NA on one side of the first connection structure 23 facing towards the display region AA in the second direction D2 further includes a hole setting region NA2. The display panel 10 further includes a first signal line 291 and a second signal line 292. The first signal line 291 and the second signal line 292 are located on two sides of the hole setting region NA2 and disposed in different layers. The first signal line 291 is electrically connected to the second signal line 292 in the hole setting region NA2. Exemplarily, the first signal line 291 extends to the shift register circuit in the non-display region NA to be connected to the scan driving signal circuit 261 or the light emission driving signal circuit 262. The second signal line 292 extends to the display region AA to be connected to a pixel driving circuit 7 in a sub-pixel 12. With this arrangement, the electrical connection between the first signal line 291 and the second signal line 292 in the hole setting region NA2 enables scan signals and light emission control signals to be transmitted from the non-display region NA to the display region and implements the connection of wire change, meeting the requirements of both signal transmission and layer wiring.

The hole setting region NA2 is located in the non-display region NA on one side of the first connection structure 23 facing towards the display region AA. The hole setting region NA2 is provided with a hole structure. The hole structure extends in the thickness direction of the display panel 10 and is configured to connect circuits or structures that are located in different layers and overlap in the thickness direction of the display panel 10. The first signal line 291 and the second signal line 292 are located on two sides of the hole setting region NA2, have an overlapping region, and are disposed in different layers. In this regard, the hole structure in the hole setting region NA2 helps implement the electrical connection between the first signal line 291 and the second signal line 292, thereby implementing the wire change between different layers and meeting the wiring requirements and wire connection requirements in the display region AA and the non-display region NA.

It is to be noted that FIG. 22 exemplarily illustrates only several types of hole structures. The type and number of hole structures are not limited in this embodiment and may be set flexibly according to the requirements of the display panel 10. Moreover, signal lines to be changed there may be any signal lines known to those skilled in the art, which is neither repeated nor limited here.

In some embodiments, as shown in FIG. 23, the first connection structure 23 and/or the first power bus 21 may also at least partially overlap the hole setting region NA2 in the thickness direction of the display panel 10. Specifically, at least a partial structure of the first connection structure 23 and/or the first power bus 21 facing towards the display region AA is disposed in the hole setting region NA2. As shown in FIG. 23, the first connection structure 23 and the first power bus 21 are located in the hole setting region NA2, thereby helping reduce the width of the bezel, facilitating the design of the narrow bezel, and thus facilitating the full screen.

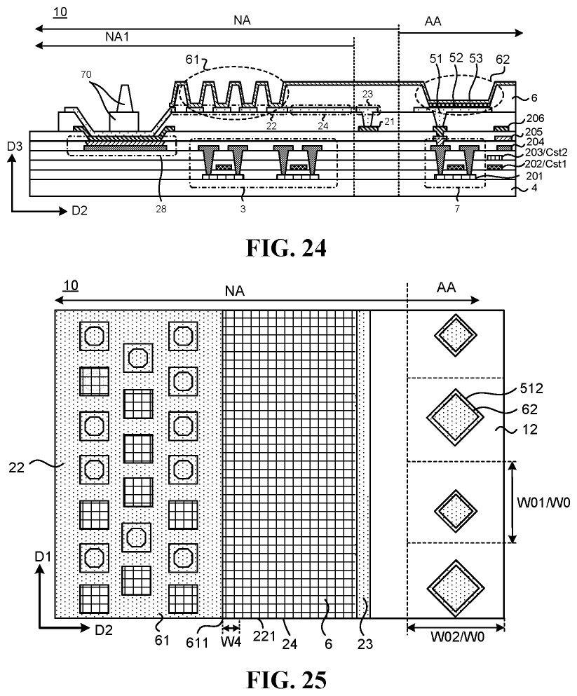

In some embodiments, as shown in FIG. 24, the display panel 10 includes a substrate 4 and a first electrode layer 51, a light emission material layer 52 and a second electrode layer 53 that are stacked in a direction away from the substrate 4 (that is, the thickness direction D3). The display panel 10 further includes a pixel defining layer 6, and the pixel defining layer 6 includes a first opening 61 and a second opening 62. The first opening 61 is located in the non-display region NA and overlaps the first power main body 22. The second opening 62 is located in the display region AA and overlaps the light emission material layer 52. The first power main body 22 is electrically insulated from the first electrode layer 51. The first power main body 22 and the first electrode layer 51 are disposed at least partially in the same layer. The first power main body 22 is electrically connected to the second electrode layer 52 through the first opening 61.

The first electrode layer 51 may be an anode layer. The anode layer in the OLED is configured to be connected to an output terminal of the pixel driving circuit. 512 denotes the anode structure in the OLED. Exemplarily, referring to FIG. 18, the anode layer may be connected to the node N4. The second electrode layer 53 is a cathode layer. The cathode layer in the OLED is configured to be connected to a power signal line. Exemplarily, referring to FIG. 18, the cathode layer may be connected to a power signal line for transmitting PVEE signals. Exemplarily, the first electrode layer 51 may be a reflective metal layer. The second electrode layer 53 may be a transparent conductive layer. Accordingly, the light emitted by the OLED is emitted as much as possible from a side where the second electrode layer 53 is located, improving display effect.

The first electrode layer 51 and the first power main body 22 may be each a conductor structure disposed in a metal layer, may use the same material or different materials, are electrically insulated from each other, and are at least partially disposed in the same layer so as to make full use of related layers of the display panel.

Exemplarily, the first electrode layer 51 and the first power main body 22 are each a single-layer structure with the same thickness and are disposed only in one layer. The first electrode layer 51 and the first power main body 22 are disposed in the same layer, as shown in FIG. 24.

Exemplarily, the first electrode layer 51 and the first power main body 22 may also be each a composite-layer structure. For example, the first electrode layer 51 may include a composite layer formed of indium tin oxide (ITO), silver (Ag) and ITO. The first power main body 22 may be formed in the same layer as the first electrode layer 51, that is, by using ITO/Ag/ITO or may be formed by using at least a metal layer of the composite layer corresponding to the first electrode layer 51, which is not limited here.

The pixel defining layer 6 located in the non-display region NA includes the first opening 61. The first power main body 22 is located below the first opening 61. The second electrode layer 53 in the display region AA extends to the non-display region NA and is connected to the first power main body 22. Alternatively, the auxiliary power lines in the display region AA extend to the non-display region NA and are connected to the first power main body 22 through the first power bus.

The pixel defining layer 6 located in the display region AA includes the second opening 62. The first electrode layer 51 is located below the second opening 62. The light emission material layer 52 is filled in the second opening 62 and covers part of the upper surface of the pixel defining layer 6. The light emission material layer 52 is in contact with the first electrode layer 51 through the second opening 62.

The second electrode layer 53 is filled in the second opening 62 and covers the upper surface of the pixel defining layer 6 and the upper surface of the light emission material layer 52. The second electrode layer 53 is electrically connected to the first power main body 22 through the first opening 61.

A peripheral circuit 3 (including the shift register circuit) is located in the non-display region AA, above the substrate 4, and below the first power main body 22. The pixel driving circuit 7 is located above the substrate 4 and below the first electrode layer 51. Exemplarily, FIG. 24 illustrates the peripheral circuit 3 and the pixel driving circuit 7 by using a circuit structure including transistors. The peripheral circuit 3 and the pixel driving circuit 7 may also include other structures or wires including a capacitor known to those skilled in the art, which is not limited here.

In embodiments of the present disclosure, the first connection structure 23, the second connection structures 24, and the first power main body 22 are each located below the pixel defining layer 6. The second connection structures 24 are disposed between the first connection structure 23 and the first power main body 22 and are spaced apart. Accordingly, the first power main body 22 is connected to the first connection structure 23 through the strip-shaped (or line-shaped) second connection structures 24 spaced apart so as to be electrically connected to the first power bus 21, thereby effectively reducing the entire area of the first connection structure 23, the first power main body 22, and the second connection structures 24 on the plane where the display panel 10 is located (that is, the plane parallel to the substrate 4). The electrostatic discharge generated by the pixel defining layer 6 to be conducted downward along the overlapping portion is greatly reduced, thereby reducing the generation of dark spots and improving display effect and product yield.

Moreover, as shown in FIGS. 24 and 25, the first opening 61 is disposed in the pixel defining layer 6 at the position of the first power main body 22 so that the electrical connection between the first power main body 22 and the second electrode layer 53 is achieved. Moreover, in the region of the first opening 61, the overlapping region between the first power main body 22 and the pixel defining layer 6 may include multiple holes. The pixel defining layer 6 in an island structure is retained at a position corresponding to the hole. Through the island structure of the pixel defining layer 6, the hole in the first power main body 22 is edged with pixel defining layer 6 and insulated to prevent a metal material in the first power main body 22, for example, silver, from precipitating out from an edge of the hole in the preparation procedure of the display panel, thereby avoiding a blind spot generated therefrom. Moreover, the hole in the first power main body 22 may provide a channel for the heat overflow, gas overflow and outward discharge of a layer located below the hole. Additionally, the arrangement of the island structure of the pixel defining layer 6 increases the area of the second electrode layer 53 and reduces the resistance. The planar Z-shaped arrangement of the island structure enables the flow of an organic encapsulation layer in an organic encapsulation structure to be controlled, helping flexibly control the encapsulation procedure of the display panel.

It is to be understood that a barrier wall 70 is also disposed in the non-display region NA for blocking an overflow of an organic material in a thin-film encapsulation layer (not shown). The thin-film encapsulation layer is disposed on one side of the second electrode layer 53 facing away from the substrate 4 and generally includes a first inorganic layer, an organic layer, and a second inorganic layer that are disposed in the direction away from the substrate. The pixel defining layer 6 and another organic layer or inorganic layer below the pixel defining layer 6 may also serve as the barrier wall 70.

In some embodiments, with continued reference to FIG. 24, the non-display region NA further includes a first non-display region NA1 disposed on one side of the first connection structure 23 facing away from the display region AA. The first power main body 22 is located in the first non-display region NA1. A first power lead 28 is disposed in the first non-display region NA1. The first power lead 28 and the first power bus 21 are at least partially disposed in the same layer.

The first power lead 28 in the first non-display region NA1 is connected to the first power main body 22 and is electrically connected to a PVDD/PVEE power (not shown). Accordingly, the auxiliary power lines are connected to the PVDD/PVEE power through the first power bus 21, the first connection structure 23, the second connection structures 24, the first power main body 22, and the first power lead 28 so that power signals are transmitted to the auxiliary power lines.

Exemplarily, as shown in FIG. 24, the first power lead 28 and the first power bus 21 are disposed on one side of the first power main body 22 facing towards the substrate 4. The first power lead 28 may be a multi-layer structure, with part of the layers of the first power lead 28 in the same layer as the first power bus 21 and the other part of the layers in the same layer as at least part of the layers in the peripheral circuit 3, which is not limited here.

In other embodiments, the first power lead 28 and the first power bus 21 are each a composite-layer structure. At least one layer in a composite layer corresponding to the first power lead 28 and a composite layer corresponding to the first power bus 21 is in the same layer, which is not limited here.

In embodiments of the present disclosure, the preceding same-layer arrangement facilitates the electrical connection between the first power lead 28 and the first power bus 21 and improves layer utilization.

In the preceding embodiments, the auxiliary power lines in the display region AA may be configured to transmit at least one of PVEE signals or PVDD signals. Exemplarily, auxiliary power lines in the same direction (for example, the lateral direction) are electrically connected and are electrically insulated from auxiliary power lines in the other direction (for example, the longitudinal direction) so that auxiliary power lines in two different directions are configured to transmit different power signals, that is, the PVEE signals or the PVDD signals. Alternatively, auxiliary power lines in two different directions are electrically connected to transmit the same power signals, which is not limited here.

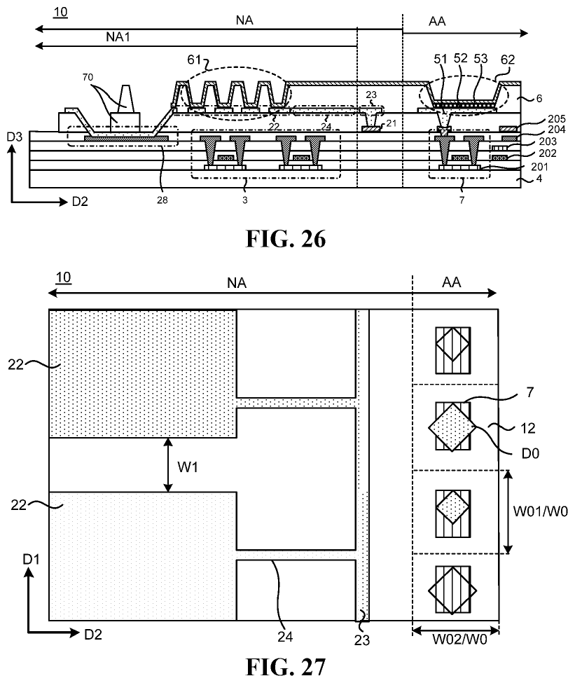

In some embodiments, as shown in FIG. 26, the non-display region NA further includes the first non-display region NA1 disposed on one side of the first connection structure 23 facing away from the display region AA. The first power main body 22 is located in the first non-display region NA1. The first power lead 28 is disposed in the first non-display region NA1. The first power lead 28 is disposed on one side of the first power bus 21 facing towards the substrate 4.

In this embodiment, the first power lead 28 and the first power bus 21 are disposed in different layers. The first power lead 28 is located below the first power bus 21 and may be arranged in other layers in the display panel 10, such as a layer where the auxiliary power lines are located, a layer where the peripheral circuit is located, or at least one of other layers known to those skilled in the art.

In the preceding embodiment, the first power lead 28 may be stacked by using a layer (the is, the first electrode layer 51) where the first power main body 22 is located or a metal layer below the first electrode layer 51, thereby making full use of layers and preventing a via hole from being excessively deep so as to reduce technique difficulty.

In some embodiments, with continued reference to FIGS. 25 and 26, the display region further includes the sub-pixels 12 arranged in an array. In the direction of the display region AA pointing to the non-display region NA, the distance W4 between a boundary of the first power main body 22 facing towards the display region AA and a boundary of the first opening 61 facing towards the display region AA is less than or equal to the width W0 of a single sub-pixel 12.

The direction of the display region AA pointing to the non-display region NA is the lateral direction for the non-display region NA on the left side of the display region AA or the right side of the display region AA and is the longitudinal direction for the non-display region NA on the upper side of the display region AA. The lateral direction (that is, the second direction D2) shown in FIGS. 25 and 26 is used as an example for description hereinafter.

As shown in FIGS. 25 and 26, the first opening 61 overlaps the first power main body 22 in the thickness direction D3 of the display panel 10. The vertical projection of the first opening 61 in the thickness direction D3 is located in the first power main body 22. The first opening 61 is configured to electrically connect the second electrode layer 53 to the first power main body 22. The pixel defining layer 6 in the island structure is retained in the first opening 61. Beneficial effects corresponding to the island structure may be understood with reference to the preceding description, which is not repeated here.

Exemplarily, with orientations shown in FIGS. 25 and 26 as an example, the boundary of the first opening 61 facing towards the display region AA is the right boundary 611 of the first opening 61 of the pixel defining layer 6. The boundary of the first power main body 22 facing towards the display region AA is the right boundary 221 of the first power main body 22. The right boundary 611 of the first opening 61 of the pixel defining layer 6 is located on the left side of the right boundary 221 of the first power main body 22, that is, on one side away from the display region AA. The distance W4 between the boundary of the first power main body 22 facing towards the display region AA and the boundary of the first opening 61 facing towards the display region AA is in fact the distance between the right boundary 221 of the first power main body 22 and the right boundary 611 of the first opening 61 of the pixel defining layer 6.

In this embodiment, the width W0 of a single sub-pixel 12 may be understood with reference to the preceding description, which is not repeated here. The arrangement in which the distance W4 between the boundary 221 of the first power main body 22 facing towards the display region AA and the boundary 611 of the first opening 61 facing towards the display region AA is less than or equal to the width of a single sub-pixel 12, reducing the overlapping area of the first power main body 22 and the pixel defining layer 6, thereby reducing the ability of the electrostatic discharge generated by the pixel defining layer 6 to be conducted downward along the first power main body 22, helping alleviate electrostatic discharge, and reducing the generation of dark spots.

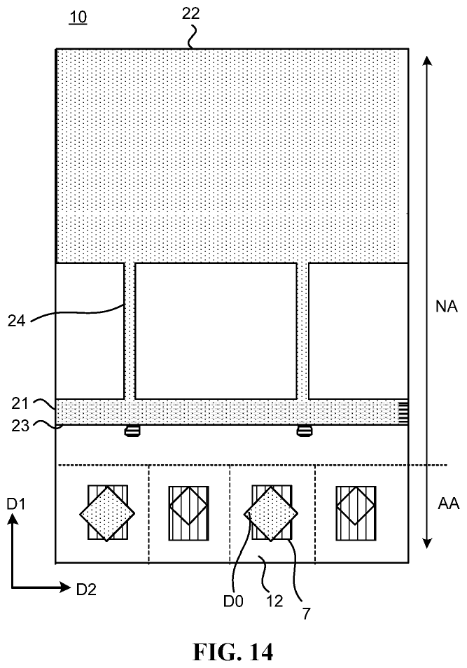

In some embodiments, with continued reference to any one of FIGS. 2, 4, 5, 9, 11, 14 to 17, 20 to 23, and 25, the first power main body 22 is a continuous single block structure. In such a structure, the first connection structure may be a single block structure or a split structure, which is not limited here.

In some embodiments, as shown in FIGS. 27, the display region further includes the sub-pixels 12 arranged in an array. The first power main body 22 is disconnected at a first preset distance W1. The first preset distance W1 is greater than or equal to the width W0 of 1/10 sub-pixels 12.

The width W0 of a single sub-pixel 12 may be understood with reference to the preceding description, which is not repeated here.

The difference between these embodiments of the present disclosure and the preceding embodiments lies in that the first power main body 22 is not a continuous, integral structure but is disconnected into at least two structures. That is, two or more first power main bodies 22 may be provided. The gap between two adjacent first power main bodies 22 is the first preset distance W1. The gap may be understood as the missing portion between two first power main bodies 22, as shown in FIG. 27.

In other embodiments, the gap between two first power main bodies 22 may also be defined by two identical points in two first power main bodies 22, for example, start points in two first power main bodies 22 in the same extension direction, end points in two first power main bodies 22 in the same extension direction, or any intermediate points in two first power main bodies 22 in the same extension direction, which is not limited here. In this structure, the first connection structure 23 may be an integral structure or a disconnected, split structure. A disconnection point of the first connection structure 23 is misaligned with a disconnection point of each first power main body 22 so as to guarantee that they serve as a whole and can supply power signals to the auxiliary power lines in the display region AA. The structure of the first power main body 22 is described exemplarily hereinafter.

In the preceding embodiments, at least one of the first power main body 22 or the first connection structure 23 is a continuous structure. Specifically, the first power main body 22 is a disconnected block-shaped structure, and the first connection structure 23 is a continuous strip-shaped structure; alternatively, the first power main body 22 is a continuous block-shaped structure, and the connection structure 23 is a disconnected strip-shaped structure; alternatively, the first power main body 22 is a continuous block-shaped structure, and the first connection structure 23 is a continuous strip-shaped structure. Alternatively, the first power main body 22 and the first connection structure 23 are each a disconnected structure, and a disconnection point of the first power main body 22 is misaligned with a disconnection point of the first connection structure 23 as long as it guarantees that the first power main body 22 and the first connection structure 23 serve as a whole to supply power signals to the auxiliary power lines in the display region AA, which is not limited here.

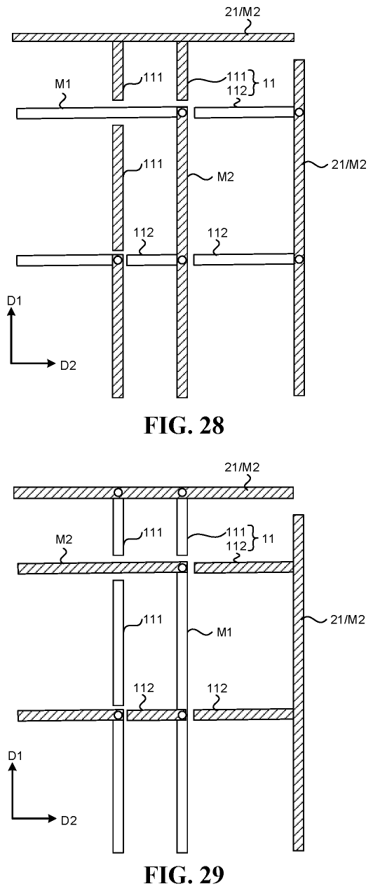

In some embodiments, as shown in FIGS. 28 and 29, the display panel includes the substrate (not shown), and a first metal layer M1 and a second metal layer M2 that are stacked in the direction away from the substrate. The auxiliary power lines 11 are located in at least one of the first metal layer M1 or the second metal layer M2. The first power bus 21 is located in at least one of the first metal layer M1 or the second metal layer M2.

Exemplarily, referring to FIG. 24 or 26, the first metal layer M1 and the second metal layer M2 are each located between the substrate 4 and the first electrode layer 51. Moreover, the first metal layer M1 is closer to the substrate 4 than the second metal layer M2. That is, the second metal layer M2 is closer to the first electrode layer 51 than the first metal layer M1.

Exemplarily, the first power main body 22, the first connection structure 23, and the second connection structures 24 may be disposed in the same layer and located in the first electrode layer 51. On this basis, the first power bus 21 may be disposed in the second metal layer M2 to facilitate the electrical connection between the first power bus 21 and the first connection structure 23 in the first electrode layer 51, to simplify structures, and to simplify procedures, as shown in FIG. 28 or 29. In other embodiments, the first power bus 21 may be located in only the first metal layer M1 or in both the first metal layer M1 and the second metal layer M2 and may be set based on the wiring and procedure requirements of the display panel, which is not limited here.

In the preceding embodiments, the auxiliary power lines 11 may be located in the first metal layer M1, located in the second metal layer M2, or segmented in the first metal layer M1 and the second metal layer M2 so as to improve the wiring uniformity of at least one of the first metal layer M1 or the second metal layer M2.

Exemplarily, as shown in FIG. 28 or 29, the auxiliary power lines 11 are located in the first metal layer M1 and the second metal layer M2. The first power bus 21 is located in the second metal layer M2.

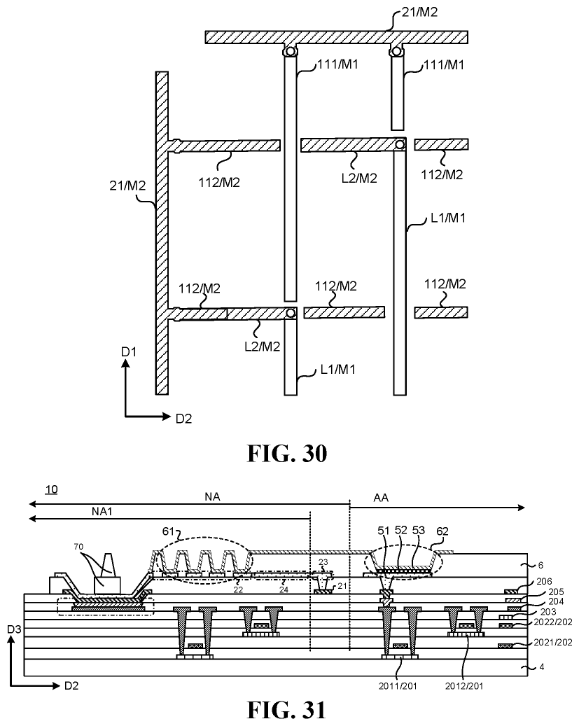

In some embodiments, as shown in FIG. 30, the display panel includes the substrate (not shown), and the first metal layer M1 and the second metal layer M2 that are stacked in the direction away from the substrate. The first auxiliary power line 111 and the first connection line segment L1 are located in at least one of the first metal layer M1 or the second metal layer M2. The second auxiliary power line 112 and the second connection line segment L2 are located in at least the other one of the first metal layer M1 or the second metal layer M2. The first power bus 21 is located in at least one of the first metal layer M1 or the second metal layer M2.

Exemplarily, referring to FIG. 24 or 26, the first metal layer M1 and the second metal layer M2 are each located between the substrate 4 and the first electrode layer 51. Moreover, the first metal layer M1 is closer to the substrate 4 than the second metal layer M2. That is, the second metal layer M2 is closer to the first electrode layer 51 than the first metal layer M1.

Exemplarily, the first power main body 22, the first connection structure 23, and the second connection structures 24 may be disposed in the same layer and located in the first electrode layer 51. On this basis, the first power bus 21 may be disposed in the second metal layer M2 to facilitate the electrical connection between the first power bus 21 and the first connection structure 23 in the first electrode layer 51, to simplify structures, and to simplify procedures, as shown in FIG. 30. In other embodiments, the first power bus 21 may be located in only the first metal layer M1 or in both the first metal layer M1 and the second metal layer M2 and may be set based on the wiring and procedure requirements of the display panel, which is not limited here.

Exemplarily, as shown in FIG. 30, the first auxiliary power line 111 and the first connection line segment L1 are located in the first metal layer M1. The second auxiliary power line 112 and the second connection line segment L2 are located in the second metal layer M2. The first power bus 21 is located in the second metal layer M2.

In other embodiments, the first auxiliary power line 111 and the first connection line segment L1 may also be located in the second metal layer M2, and the second auxiliary power line 112 and the second connection line segment L2 may also be located in the first metal layer M1. Alternatively, the first auxiliary power line 111 and the first connection line segment L1 are located in both the first metal layer M1 and the second metal layer M2, and the second auxiliary power line 112 and the second connection line segment L2 are also located in both the first metal layer M1 and the second metal layer M2, which is not limited here. Moreover, in FIGS. 28 to 30, the first power bus 21 extending in the first direction D1 may also be electrically connected to the first power bus 21 extending in the second direction D2, which is not limited here.

In some embodiments, among the auxiliary power lines and connection line segments, auxiliary power lines and connection line segments in the same direction are located in the same metal layer, and auxiliary power lines and connection line segments in different directions are located in different metal layers. That is, the first auxiliary power line 111 and the first connection line segment L1 are located in the same metal layer, and the second auxiliary power line 112 and the second connection line segment L2 are located in the same metal layer, thereby implementing the even wiring in each metal layer. Moreover, the first power bus 21 is located in a metal layer closer to the first electrode layer 51 amid the first metal layer M1 and the second metal layer M2 so as to simplify structures and procedures.

In the preceding embodiments, the display panel may also include a buffer layer located between the substrate and the peripheral circuit. The buffer layer may be configured to flatten the substrate surface and block the diffusion of elements in the substrate to a corresponding layer of the peripheral circuit so as to guarantee the stability of the entire structure and performance of the display panel.

In the preceding embodiments, the display panel may include a gate metal layer, an active layer, and a source-drain metal layer. The active layer may be disposed on one side of the gate metal layer facing the substrate (as shown in FIG. 24 or 26) or on one side of the gate metal layer facing away from the substrate, which is not limited here.

In the preceding embodiments, the active layer may be a single-layer structure. For example, the active layer may be an LTPS layer as shown in FIG. 24 or 26, with an LTPS transistor formed Accordingly. Alternatively, the active layer is a dual-layer structure. For example, the active layer includes an LTPS layer and a metal-oxide layer as shown in FIG. 31, with an LTPS transistor and an oxide transistor formed Accordingly, so as to form a Low Temperature Polycrystalline Oxide (LTPO) display panel. Exemplarily, metal oxides may include IGZO or other types of oxides known to those skilled in the art and able to be used in the active layer, which is not limited here.

Exemplarily, as shown in FIG. 24, the display panel 10 may include the substrate 4, the active layer 201, the gate metal layer 202, a capacitor metal layer 203, the source-drain metal layer 204, a first auxiliary metal layer 205, and a second auxiliary metal layer 206 in the thickness direction D3 of the display panel 10.

The active layer 201 may be provided with the active region of each transistor. The gate metal layer 202 may be provided with the gate of each transistor and may also be provided with each scan signal line and each light emission control signal line; alternatively, the gate metal layer 202 may be provided with one plate Cst1 of each storage capacitor. The capacitor metal layer 203 may be provided with the other plate Cst2 of each storage capacitor and may also be provided with each reference signal line. The source-drain metal layer 204 may be provided with the source and drain of each transistor and may also be provided with each data line or each power signal line. The first auxiliary metal layer 205 and the second auxiliary metal layer 206 may be provided with each auxiliary power line and each connection line segment and may also be provided with each data line or each power signal line.

On this basis, the first auxiliary metal layer 205 may be used as the first metal layer in the preceding embodiments, and the second auxiliary metal layer 206 may be used as the second metal layer in the preceding embodiments.

Exemplarily, compared with the display panel shown in FIG. 24, the display panel shown in FIG. 26 does not include the second auxiliary metal layer 206. In this structure, the first auxiliary metal layer 205 may be used as the second metal layer in the preceding embodiments. At least one of the source-drain metal layer 204, the capacitor metal layer 203, or the gate metal layer 202 may be used as the first metal layer in the preceding embodiments.

Exemplarily, FIG. 31 illustrates the structure of the LTPO display panel. Compared with the display panel shown in FIG. 24, the display panel shown in FIG. 31 includes not only an LTPS transistor but also an oxide transistor. Active layers 201 include an LTPS active layer 2011 and an oxide active layer 2012. Gate metal layers 202 include an LTPS gate layer 2021 and an oxide gate layer 2022. In this structure, the first auxiliary metal layer 205 may be used as the first metal layer in the preceding embodiments, and the second auxiliary metal layer 206 may be used as the second metal layer in the preceding embodiments.

In other embodiments, when the LTPO display panel has only the first auxiliary metal layer and does not include the second auxiliary metal layer, the first auxiliary metal layer 205 may be used as the second metal layer in the preceding embodiments. At least one of the source-drain metal layer 204, the capacitor metal layer 203, the LTPS gate layer 2021, or the oxide gate layer 2022 may be used as the first metal layer in the preceding embodiments, which is not limited here.

In the preceding embodiments, at least one layer of the gate metal layers in the display panel, the source-drain metal layer in the display panel, the capacitor metal layer in the display panel, or other conventional metal layers in the display panel may be used for arranging the auxiliary power lines, the connection line segments, and the first power bus. Moreover, the first power bus is located in the metal layer closest to the first electrode layer. Therefore, no additional metal layer is acquired or the number of additionally-added metal layers is reduced regarding the auxiliary power lines, the connection line segments, and the first power bus, thereby guaranteeing less preparation procedure, guaranteeing fewer layers in the display panel, and facilitating the thin and light design of the display panel.

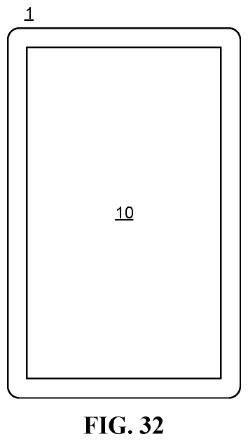

Based on the preceding embodiments, an embodiment of the present disclosure further provides a display device. Exemplarily, as shown in FIG. 32, the display device 1 includes any preceding display panel 10 and has the corresponding beneficial effects. To avoid a repeated description, the details are not repeated here.

The display device 1 includes, but is not limited to, a mobile phone, a tablet computer, an in-vehicle computer, a smart wearable device having a display function and another structural component having a display function, which is neither repeated nor limited here.

It is to be noted that herein, relationship terms such as “first” and “second” are used merely for distinguishing one entity or operation from another and do not necessarily require or imply any such actual relationship or order between these entities or operations. Furthermore, the term “comprising”, “including” or any other variant thereof is intended to encompass a non-exclusive inclusion so that a process, method, article, or device that includes a series of elements not only includes the expressly listed elements but may also include other elements that are not expressly listed or are inherent to such process, method, article, or device. In the absence of more restrictions, the elements defined by the statement “including a . . . ” do not exclude the presence of additional identical elements in the process, method, article or device that includes the elements.

The preceding are embodiments of the present disclosure to enable those skilled in the art to understand or implement the present disclosure. Various modifications made to these embodiments are apparent to those skilled in the art, and the general principles defined herein may be implemented in other embodiments without departing from the spirit or scope of the present disclosure. Therefore, the present disclosure is not limited to the embodiments described herein but is to accord with the widest scope consistent with the principles and novel features disclosed herein.

What is claimed is:

1. A display panel, comprising a display region and a non-display region at least partially surrounding the display region, wherein
the display region comprises auxiliary power lines;
the non-display region comprises a first power main body and a first power bus; and
the auxiliary power lines are electrically connected to the first power main body through the first power bus.

2. The display panel according to claim 1, wherein the non-display region comprises a fan-out region disposed on one side of the display region in a first direction, the display region comprises a first display region and a second display region, the second display region is disposed on at least one side of the first display region in a second direction, and the second direction intersects the first direction;
the fan-out region comprises a plurality of fan-out wires, and each of the first display region and the second display region comprises a plurality of data lines extending in the first direction and arranged in the second direction;
a data line is connected to one of the plurality of fan-out wires, wherein a data line of the plurality of data lines in the second display region is connected to a respective fan-out wire of the plurality of fan-out wires through a connection wire;
the connection wire is located in the display region and comprises a first connection line segment extending in the first direction and a second connection line segment extending in the second direction, the first connection line segment is electrically connected to the respective fan-out wire, and the second connection line segment is electrically connected to the data line in the second display region;
the auxiliary power lines comprise at least one of a first auxiliary power line extending in the first direction or a second auxiliary power line extending in the second direction;
the first auxiliary power line is disposed in a same layer as the first connection line segment, and the first auxiliary power line is insulated from the first connection line segment and the second connection line segment; and
the second auxiliary power line is disposed in a same layer as the second connection line segment, and the second auxiliary power line is insulated from the first connection line segment and the second connection line segment.

3. The display panel according to claim 2, wherein
first connection line segments in connection wires are disposed in a same layer as second connection line segments in the connection wires, and first auxiliary power lines in the auxiliary power lines are disposed in a same layer as second auxiliary power lines in the auxiliary power lines; or
the first connection line segments in the connection wires are disposed in a same layer, the second connection line segments in the connection wires are disposed in a same layer, and the first connection line segments and the second connection line segments are disposed in different layers; and the first auxiliary power lines in the auxiliary power lines are disposed in a same layer, the second auxiliary power lines in the auxiliary power lines are disposed in a same layer, and the first auxiliary power lines and the second auxiliary power lines are disposed in different layers.

4. The display panel according to claim 2, wherein the non-display region further comprises a first connection structure extending in at least one direction of the first direction or the second direction;
the first connection structure is disposed on one side of the first power main body facing towards the display region; and
the first power bus is electrically connected to the first power main body through the first connection structure.

5. The display panel according to claim 4, wherein the display region further comprises sub-pixels arranged in an array;
the first connection structure is a continuous strip-shaped structure, or the first connection structure is disconnected at a second preset distance; and
the second preset distance is greater than or equal to a width of 1/10 of the sub-pixels.

6. The display panel according to claim 4, wherein a vertical projection of the first power bus on a plane where the first connection structure is located overlaps at least the first connection structure; and
a ratio of an overlapping area to an area of the first connection structure is P, wherein 50%≤P≤100%.

7. The display panel according to claim 4, wherein the non-display region further comprises a second connection structure;
the second connection structure is located between the first connection structure and the first power main body; and
the first connection structure is electrically connected to the first power main body through the second connection structure.

8. The display panel according to claim 7, wherein the non-display region further comprises a reset signal line and a shift register circuit;
the reset signal line extends in the first direction and is arranged in the second direction;
at least one reset signal line is located between the first power bus and the first power main body; and
the shift register circuit is disposed on one side of the reset signal line facing away from the display region.

9. The display panel according to claim 8, wherein the shift register circuit overlaps the first power main body in a thickness direction of the display panel.

10. The display panel according to claim 8, wherein the shift register circuit comprises a scan driving signal circuit and a light emission driving signal circuit, the scan driving signal circuit is connected to a sub-pixel in the display region through a first transmission line, and the light emission driving signal circuit is connected to the sub-pixel in the display region through a second transmission line; and
the second connection structure overlaps at least one of the first transmission line or the second transmission line in a thickness direction of the display panel.

11. The display panel according to claim 7, wherein the first power bus further overlaps the second connection structure in a thickness direction of the display panel.

12. The display panel according to claim 7, wherein the display region further comprises sub-pixels arranged in an array; and
a distance between two adjacent second connection structures in an arrangement direction of the second connection structures is greater than or equal to a width of a single one of the sub-pixels in the arrangement direction.

13. The display panel according to claim 4, wherein the non-display region on one side of the first connection structure facing towards the display region in the second direction further comprises a hole setting region; and
the display panel further comprises a first signal line and a second signal line, the first signal line and the second signal line are located on two sides of the hole setting region and disposed in different layers, and the first signal line is electrically connected to the second signal line in the hole setting region.

14. The display panel according to claim 4, further comprising: a substrate and a first electrode layer, a light emission material layer and a second electrode layer that are stacked in a direction away from the substrate; and
a pixel defining layer comprising a first opening and a second opening, wherein the first opening is located in the non-display region and overlaps the first power main body, and the second opening is located in the display region and overlaps the light emission material layer;
wherein the first power main body is electrically insulated from the first electrode layer, and the first power main body and the first electrode layer are disposed at least partially in a same layer; and
the first power main body is electrically connected to the second electrode layer through the first opening.

15. The display panel according to claim 14, wherein the non-display region on one side of the first connection structure facing away from the display region further comprises a first non-display region, the first power main body is located in the first non-display region, and a first power lead is disposed in the first non-display region, wherein
the first power lead and the first power bus are at least partially disposed in a same layer; or
the first power lead is disposed on one side of the first power bus facing the substrate.

16. The display panel according to claim 14, wherein the display region comprises sub-pixels arranged in an array; and
in a direction of the display region pointing to the non-display region, a distance between a boundary of the first power main body facing towards the display region and a boundary of the first opening facing towards the display region is less than or equal to a width of a single one of the sub-pixels.

17. The display panel according to claim 1, wherein the display region comprises sub-pixels arranged in an array, wherein
the first power main body is a continuously block-shaped structure; or
the first power main body is disconnected at a first preset distance, and the first preset distance is greater than or equal to a width of 1/10 of the sub-pixels.

18. The display panel according to claim 1, further comprising: a substrate, and a first metal layer and a second metal layer that are stacked in a direction away from the substrate, wherein
the auxiliary power lines are located in at least one of the first metal layer or the second metal layer; and
the first power bus is located in at least one of the first metal layer or the second metal layer.

19. The display panel according to claim 2, further comprising a substrate, and a first metal layer and a second metal layer that are stacked in a direction away from the substrate, wherein
the first auxiliary power line and the first connection line segment are located in at least one of the first metal layer or the second metal layer, and the second auxiliary power line and the second connection line segment are located in at least another one of the first metal layer or the second metal layer; and
the first power bus is located in at least one of the first metal layer or the second metal layer.

20. A display device, comprising a display panel, wherein the display panel comprises:
a display region and a non-display region at least partially surrounding the display region, wherein
the display region comprises auxiliary power lines;
the non-display region comprises a first power main body and a first power bus; and
the auxiliary power lines are electrically connected to the first power main body through the first power bus.
